(19) United States
(12) Patent Application Publication
(10) Pub. No.: US 2006/0082285 A1
(43) Pub. Date: Apr. 20, 2006

(54) Top emitting organic light emitting device

(75) Inventors: Chung Chih Wu, Taipei City (TW); Chih Jen Yang, Luzhu Shiang (TW); Chun Liang Lin, Zhonghe City (TW); Yung Hui Yeh, Hsinchu City (TW); Chieh Wei Chen, Fengyuan City (TW)

Correspondence Address: BRUCE H. TROXELL, SUITE 1404, 5205 LEESBURG PIKE, FALLS CHURCH, VA, 22041, US

(73) Assignee: Industrial Technology Research Institute

(21) Appl. No.: 11/115,110

(22) Filed: Apr. 27, 2005

(30) Foreign Application Priority Data
Oct. 15, 2004 (TW) 93131254

(51) Int. Cl. H05B 33/22; H05B 33/26

(52) U.S. Cl. 313/503; 313/504; 313/506

(57) ABSTRACT

A top emitting OLED is provided. The top emitting OLED comprises a substrate, a first electrode layer, an organic layer, and a second electrode layer. Wherein, the first electrode layer is formed on the substrate, the organic layer is formed on the first electrode layer, and the second electrode layer with a first refractive index is formed on the organic layer. Moreover, an anti-reflective layer with a second refractive index is formed on the second electrode layer. The first refractive index is different from the second refractive index, and the first thickness is matched and cooperated with the second thickness for reducing the reflectance of the OLED on visible light region.

### FIELD OF THE INVENTION

The present invention relates to an organic light emitting device (OLED), in particular to a top emitting OLED with an anti-reflective layer.

### BACKGROUND OF THE INVENTION

Recently, organic light emitting devices (OLED) are widely used in various fields as displays. As shown in FIG. 1A, the standard structure of OLED 8 comprises a glass substrate 81, an anode layer 82, an organic layer 83, and a cathode layer 84 stacked sequentially. Wherein, the chemical structures of the materials used for making the organic layer 83 such as m-MTDATA, α-NPD, BCP (2,9-Dimethyl-4,7-diphenyl-1,10-phenanthroline), and Alq₃ are shown in FIG. 1B.

For the purpose of higher resolution and better emitting usage rate, the recent design of OLED usually adopts a design of top-emitting structure. FIG. 2 is the schematic illustration showing a conventional top emitting OLED. The top emitting OLED 9 comprises an opaque substrate 91, an anode layer 92, an organic layer 93, and a transparent cathode layer 94 stacked sequentially. The early patents regarding top emitting OLED, including U.S. Pat. No. 4,720,432, U.S. Pat. No. 4,769,292, U.S. Pat. No. 4,950,950, U.S. Pat. No. 5,776,622, and U.S. Pat. No. 5,776,623, only focused on the organic materials and the structure of the top emitting OLED. Therefore, for constructing a top-emitting OLED 9, it is commonly known that the anode layer 92 needs to be opaque, the cathode layer 94 needs to be transparent, the work function of the material of the anode layer 92 must be larger than 4 eV; the work function of the material of the cathode layer 94 must be smaller than 4 eV or consist of the multi-layer LiF/AL. However, none of those previous patents had taken optical structure into consideration, nor did they think about the requirement of the display contrast.

IBM Corporation has also disclosed several patents about top emitting OLED, such as U.S. Pat. No. 5,739,545, U.S. Pat. No. 5,714,838, U.S. Pat. No. 6,501,217 B2, and so on. The top-emitting OLED disclosed within these patents comprises: a bottom anode, being made of a metal or alloy of Al, Cu, Mo, Ti, Pt, and even made of semiconductor, a barrier layer, an anode modification layer and a plurality of organic layers, a cathode layer made of thin metal, and a protective layer of a wide bandgap semiconductor; wherein the bottom anode, the barrier layer, the anode modification layer, the plural organic layers, the cathode layer and the protective layer are stack-formed successively. However, those patents disclosed by IBM only focus on the electricity and pay no attention to the optical characters.

Universal Display Corporation (UDC) cooperating with Princeton University also published several related patents, such as U.S. Pat. No. 5,703,436, U.S. Pat. No. 5,917,280, U.S. Pat. No. 5,981,306, U.S. Pat. No. 6,046,543, U.S. Pat. No. 6,569,697B2, and so on. The objects of those patents are to provide a transparent organic light emitting device (TOLED) and to illustrate the applications of the same in stacked organic light emitting device (SOLED), which is capable of integrally forming light emitting devices of different colors on a same pixel. The content of these patents comprises device designing, device structure, material selecting, manufacturing transparent electrode, protective layer selecting, and film coating conditions, which lack the discussion focusing on top emitting devices and has not taken the contrast characters for displaying into consideration.

LUXELL Corporation also has several patents about high contrast OLED, such as U.S. Pat. No. 6,411,019 and U.S. Pat. No. 6,551,651, which focus on the bottom emitting OLED having an optical interference member added between the anode and cathode electrodes of the device for reducing reflectance. However, since the interference member is added between the anode and cathode electrodes, the work function difference of the interference member and the organic material becomes critical such that the proper selection of the material of the interference member is necessary. Nevertheless, no matter the optical interference member is mixed with the organic material forming the organic layer or is independently formed, the efficiency of charge transmitting will be influenced inevitably. The layer of the interference member includes a double-layer structure consisting a Mg:Ag metal layer and an indium tin oxide (ITO) layer, and a cathode formed on the double-layer structure.

There are still some related researches of top-emitting OLED disclosed by H. Riel of IBM Corporation, Zurich R&D lab. The foregoing top-emitting OLED is characterized by: a bottom anode made of an opaque metal such as Pt, Ir, Ni, Pd, and Mo; a top cathode, consisting of a layer of Ca with 12 nm thickness and a layer of Mo with 12 nm thickness to be the top cathode; and a layer of semiconductor material (i.e. ZnSe) coated on the top cathode; wherein the layer of ZnSe coated on the top cathode is capable of raising the optical coupling efficiency and thus further improving the emitting efficiency of the device. Nevertheless, the content of the researches only mentions the effect of efficiency affected by adjusting a single optical film that has no discussion relating to the contrast characters for displaying, not to mention the affect on the contrast characters for displaying caused by stacking optical films on the cathode of the OLED.

There are still some related researches of top-emitting OLED disclosed by M. -H. Lu of Universal Display Corporation (UDC). The foregoing top-emitting OLED is characterized by: a bottom anode made of Ag or Ni; a top cathode made of mixture metal of Mg:Ag; and an ITO layer coated on the top cathode. However, the content of the researches only focused on the device efficiency, but lacks of discussion regarding the contrast characters for displaying.

In addition, the top-emitting OLED published jointly by Z. H. Lu of University of Toronto and LUXELL Corporation is featuring by that: a double-layer of Li/Al coated with a thin film of SiO:Al is employed as the top electrode. Since the SiO: Al film has a small amount of aluminum, he film thus possesses a certain conductivity. However, the content of the researches still did not mention the device reflectance and the contrast characters for displaying.

The research team leaded by Prof. L. S. Hung of City University of Hong Kong aims at the improvement of the display contrast for bottom emitting OLED. The foregoing research employs the electron transporting layer of Alq₃ coated with additional multi-layer structure of Sm/Alq₃/Al as the cathode of the OLED, wherein the multi-layer of Sm/Alq₃/Al is addressed as phase shift layer. However, although the foregoing research can raise the display contrast, it only focuses on the bottom emitting OLED.

In the present technology, the bottom anode layer of the top emitting OLED comprises metal or semiconductor materials, so it will reflect the incident light, and thus reduce the display contrast. By virtue of this, an additional polarizer or filter will be pasted onto the surface of the display in order to reduce the reflectance and raise contrast. However, the additional film will also absorb light that diminishes the intensity of emitting. Besides, the pasting of polarizer or filter will complicate the whole manufacturing process that eventually increases the manufacturing cost.

### SUMMARY OF THE INVENTION

It is the primary object of the present invention to provide a top emitting OLED having an anti-reflective layer formed on the top electrode thereof, wherein a external light incident to the OLED is destructively interfered inside the anti-reflective layer formed with a selected material (i.e. with desirable refractive indexes) and thickness, so that the reflectance of the OLED to the visible light incident to the same will be reduced for raising the display contrast.

It is another object of the present invention to provide a top emitting OLED, which can simplify the manufacturing processes and reduce manufacturing cost by eliminating the requirement of pasting an additional polarizer or filter on the surface of the display panel.

In order to achieve the aforesaid objects, the present invention provides a top emitting OLED, comprising a substrate, a first electrode layer, an organic layer, and a second electrode layer. Wherein, the first electrode layer is formed on the substrate, the organic layer is formed on the first electrode layer, and the second electrode layer having a first refractive index and with a first thickness is formed on the organic layer. Moreover, an anti-reflective layer having a second refractive index and with a second thickness is formed on the second electrode layer. The first refractive index is different from the second refractive index, and the first thickness is matched and cooperated with the second thickness for reducing the reflectance of the OLED on the visible light region and improving the display contrast thereof.

The first electrode of the OLED according to the present invention can be of made of metal or other conductive materials, such as Au, Ag, Cu, Al, Cr, Mo, Ti, Ni, Pt, Ir, Pd, ITO, or the stack structure or mixture thereof.

In addition, the organic layer of the OLED according to the present invention can be a single-layered organic layer with both the functions of light-emitting and positive/negative charge transporting. The organic layer also can be a multi-layer structure, such as (1) an electron hole transporting layer and an electron-transporting/light-emitting layer sequentially forming on the first electrode, (2) an electron-hole-transporting/light-emitting layer and an electron transporting layer sequentially forming on the first electrode, (3) an electron hole transporting g layer, a light-emitting layer, and an electron transporting layer sequentially forming on the first electrode, (4) an electron transporting layer, a light-emitting layer, and an electron hole transporting layer sequentially forming on the first electrode, (5) an electron-transporting/light-emitting layer and an electron hole layer sequentially forming on the first electrode.

### BRIEF DESCRIPTION OF THE DRAWINGS

FIG. 1A is the schematic illustration showing a conventional OLED.

FIG. 1B shows the chemical structures of the common organic materials of m-MTDATA, α-NPD, BCP, and Alq₃.

FIG. 2 is the schematic illustration showing a conventional top emitting OLED.

FIG. 3 is the schematic illustration showing a top emitting OLED of the present invention.

FIG. 4A is the schematic illustration showing a top emitting OLED of the present invention having two anti-reflective layers.

FIG. 4B is the schematic illustration showing a top emitting OLED of the present invention having a single anti-reflective layer.

FIG. 5 is the profile of reflectance with response to wavelength according to the first embodiment of the present invention.

FIG. 6 is the profile of current density and luminance with response to voltage according to the first embodiment of the present invention.

FIG. 7 is the profile of reflectance with response to wavelength according to the second embodiment of the present invention.

FIG. 8 is the profile of reflectance with response to wavelength according to the third embodiment of the present invention.

FIG. 9 is the profile of reflectance with response to wavelength according to the fourth embodiment of the present invention.

FIG. 10 is the profile of reflectance with response to wavelength according to the fifth embodiment of the present invention.

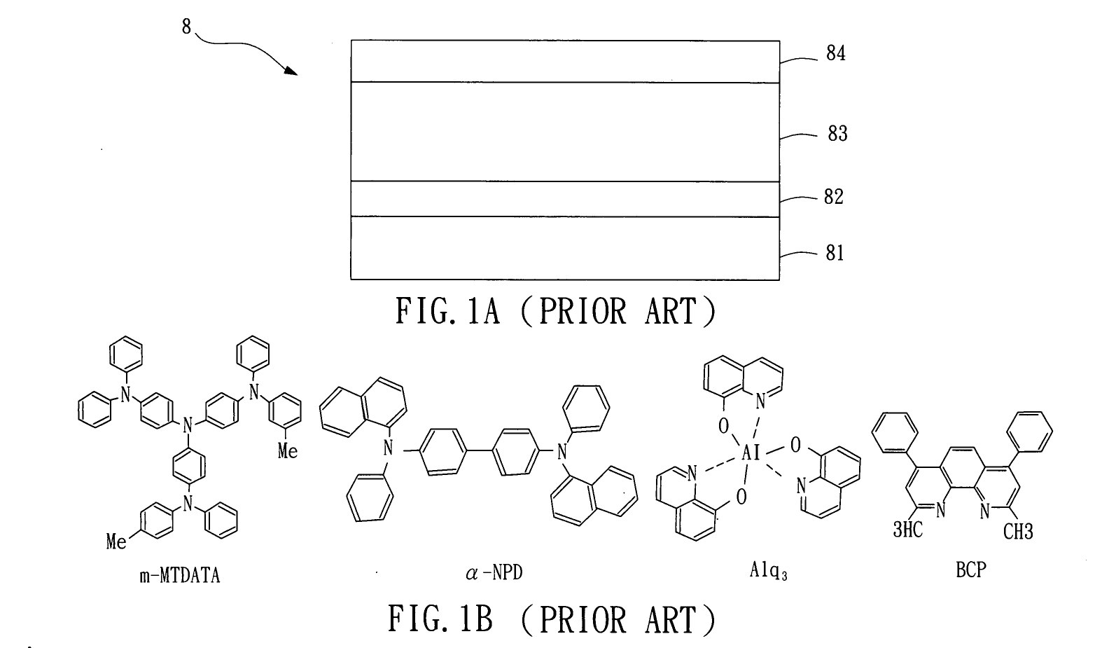

### DETAILED DESCRIPTION OF THE INVENTION

Matched with corresponding drawings, the preferable embodiments of the invention are presented as following and hope they will benefit your esteemed reviewing committee members in reviewing this patent application favorably.

FIG. 3 is the schematic illustration showing a top emitting OLED of the present invention. The top emitting OLED structure 1 of the present invention includes a first electrode layer 12 stacked on a substrate 11, an organic layer 13 formed on the first electrode layer 12, a second electrode layer 14 formed on the organic layer 13, and an anti-reflective layer 15 formed on the second electrode layer 14, wherein, the second electrode layer 14 has a first refractive index n1 and is formed with a first thickness h1, and the anti-reflective layer 15 has a second refractive index n2 and is formed with a second thickness of h2, and the first refractive index n1 is different to the second refractive index n2.

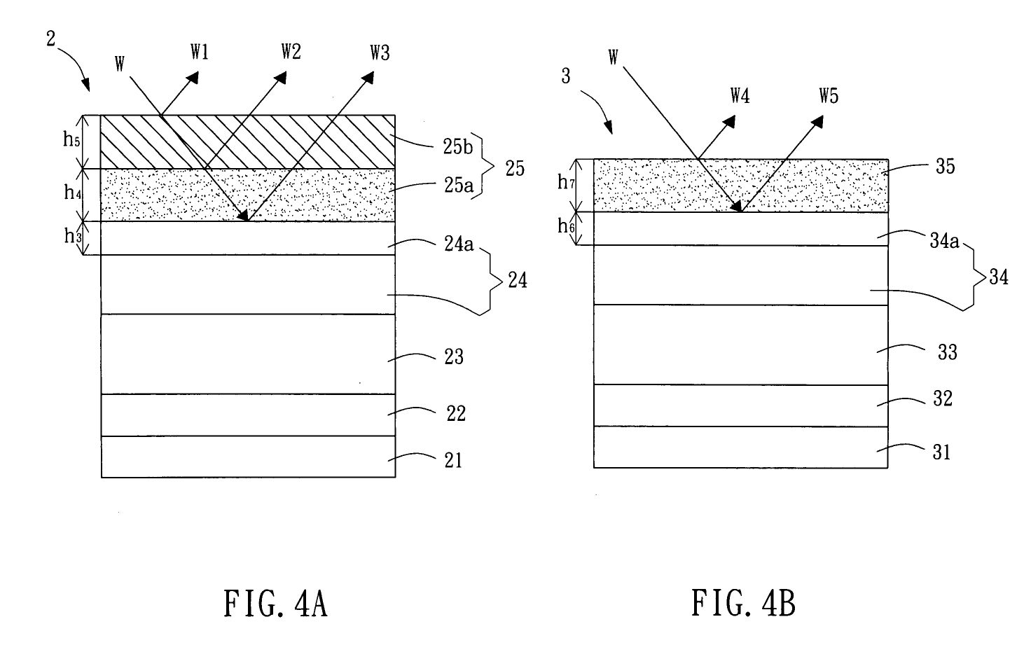

FIG. 4A is the schematic illustration showing the first status of a top emitting OLED having two anti-reflective layers according to the present invention. The OLED 2 of FIG. 4A has a structure similar to that of FIG. 3, which comprises a substrate 21, a first electrode layer 22, an organic layer 23, a second electrode layer 24, and an anti-reflective layer 25 stacked sequentially. The second electrode layer 24 further comprises a semi-transparent thin film 24a made of a metal with a thickness h3, where h3>5 nanometer. Moreover, the anti-reflective layer 25 is consisted of a layer of first dielectric material 25a and a layer of second dielectric material 25b. Certainly, the anti-reflective layer 25 can be a multi-layer structure made of more than two dielectric materials. The layer of first dielectric material 25a and the layer of second dielectric material 25b are respectively made of a material of high and low refractive index, and respectively with the thickness of h4 and h5, such that the anti-reflective layer 25 composed of the first dielectric material 25a and the second dielectric material 25 is capable of achieving the purpose of anti-reflection. Wherein, the aforesaid the material with high refractive index is referred to those with refractive index higher than that of the organic layer, i.e. 1.8, and thus the low refractive index is lower than 1.8. As shown in FIG. 4A, a portion of the incident light W is reflected by the layer of second dielectric material 25b and becomes the reflected light W1, and the other portion will pass through the layer of second dielectric material 25b, of which a portion will be reflected by the layer of first dielectric layer 25a and then pass through the layer of second dielectric material 25b so as to become the reflected light W2; and the remaining portion which is not reflected by the layer of first dielectric material 25a will pass through the first dielectric layer 25a and then is reflect by the second electrode layer 24 to pass through the first dielectric layer 25a and the second dielectric layer 25b so as to become the reflected light W3. If the phases of W1, W2, and W3 can be counteracted, the effect of anti-reflection is achieved. In the present embodiment, the intensity and phase parameters of W1, W2, W3 can be adjusted by arranging the dielectric material 25a of high refractive index with respect to the and 25b dielectric material of low refractive indexes, so as to enhance the phenomenon of cancellation between W1, W2 and W3.

FIG. 4B is the schematic illustration showing the second status of the top emitting OLED having a single anti-reflective layer according to the present invention. The OLED 3 of FIG. 4B has a structure similar to that of FIG. 3, which comprises a substrate 31, a first electrode layer 32, an organic layer 33, a second electrode layer 34, and an anti-reflective layer 35 stacked sequentially. The second electrode layer 34 is a transparent conductive layer, or can further comprise a semi-transparent thin film 34a made of a metal with a thickness h6, where h6<5 nanometer. In addition, the anti-reflective layer 35 can be a single layer or even a multi-layer structure made of more than one dielectric materials. As shown in FIG. 4B, a portion of the incident light W is reflected by the anti-reflective layer 35 and becomes the reflected light W4, and the other portion of the incident light passing through the anti-reflective layer 35 is reflected by the second electrode layer 34 and passes through the anti-reflective layer 35 to become the reflected light W5. By choosing the appropriate anti-reflective layer 35 of certain reflective index and matched with the appropriate thickness h7, the reflected lights W4 and W5 can offset and thus reduce reflectance of the device.

The following embodiments, that is, Example 1 to Example 5, are the detail examples with reference to the aforesaid two status of the present invention. Compared with the normal top emitting OLED, these examples will show the obvious improvement of the present invention.

### EXAMPLE 1

This example illustrates the raising of contrast character basing on the aforesaid first status of the present invention.

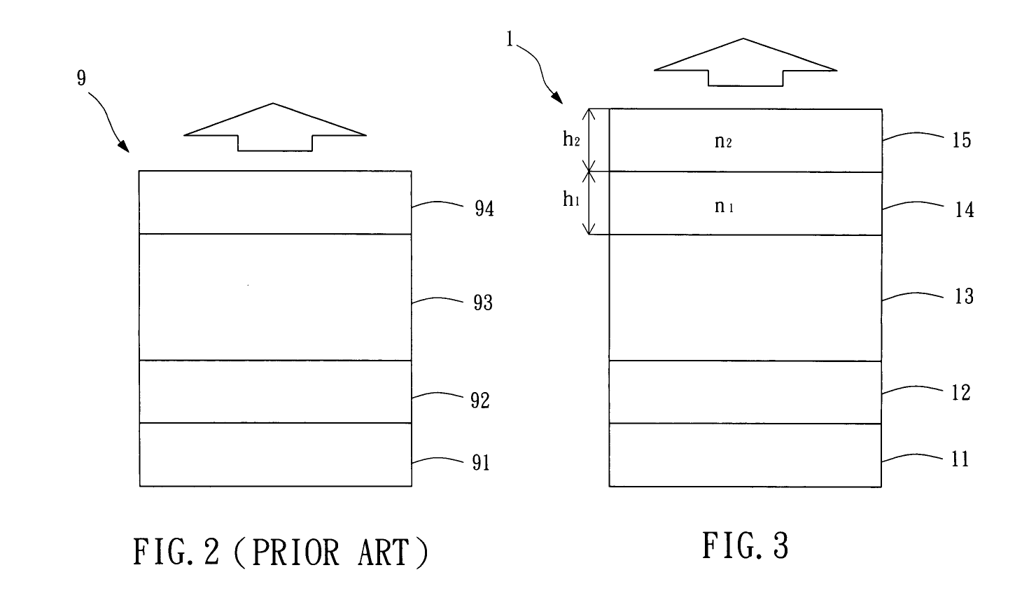

On this example, Device A is a top emitting OLED, of which the structure is similar to that shown in FIG. 2. Wherein, the substrate 91 is a glass substrate, the anode layer 92 is made of Cr with 100 nm in thickness, the organic layer 93 is consisted of a layer of m-MTDATA with 30 nm in thickness, a layer of α-NPD with 20 nm in thickness, and a layer of Alq₃ with 60 nm in thickness, and the transparent cathode layer 94 is consisted of a layer of LiF with 0.5 nm in thickness, a layer of Al with 1 nm in thickness, and a layer of Ag with 20 nm in thickness.

Device B is the top emitting OLED according to the present invention, of which the structure is shown in FIG. 4A. Wherein, the substrate 21 is a glass substrate, the first electrode layer 22 is made of Cr with 100 nm in thickness, the organic layer 23 is consisted of layer of m-MTDATA with 30 nm in thickness, a layer of α-NPD with 20 nm in thickness, and a layer of Alq₃ with 60 nm in thickness, the second electrode 24 is consisted of a layer of LiF with 0.5 nm in thickness, a layer of Al with 1 nm in thickness, and a layer of Ag with 20 nm in thickness, the first dielectric layer 25a is made of TeO₂ with refractive index 2.2 and 30 nm in thickness, and the second dielectric layer 25b is made of LiF with refractive index 1.36 and 25 nm in thickness.

In this example, each layer is formed under the high vacuum condition of 10⁻⁶ torr. In addition, the organic layers 33 and 93 are formed by thermal evaporation. In the Device A and B, the first electrode layer is made of Cr, the layer of m-MTDATA is used as the electron hole injection layer, the layer of α-NPD is used as the electron hole transmitting layer, the layer of Alq₃ is used as the electron transmitting/light-emitting layer, and the multi-layer structure of LiF/Al/Ag is used as the second electrode layer, of which LiF/Al is acted as an electron injection layer and Ag is acted as the conductive electrode for reducing sheet resistance. Moreover, in Device B, TeO₂ is used as the high refractive index material (n_{TeO2}=2.2) and LiF is used as the low refractive index material (n_{LiF}=1.36), such that the anti-reflective layer 25 is formed by successively stacking the two materials of high and low refractive indexes.

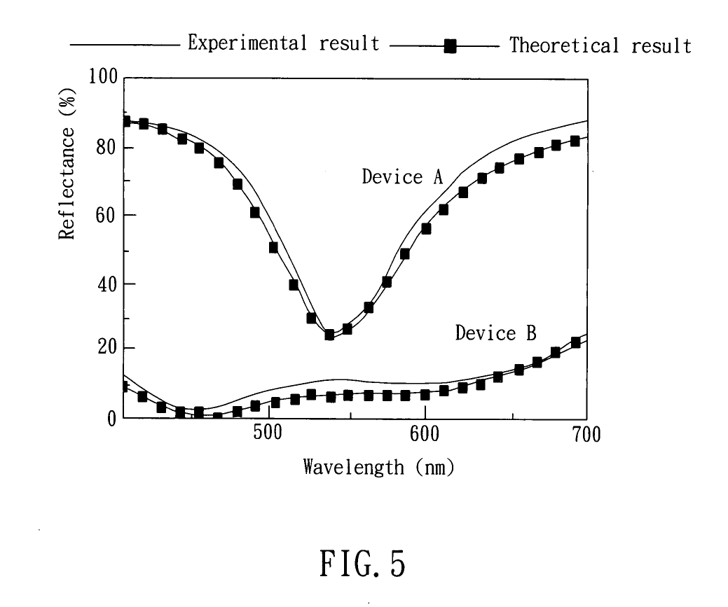

As shown in FIG. 5, the measured average reflectance of Device A in the visible light region is 66%, and that of Device B is 12%. Obviously, not only the experimental results but also the theoretically calculated results show that the reflectance in the visible light region can be greatly reduced by adding an anti-reflective layer on the second electrode layer.

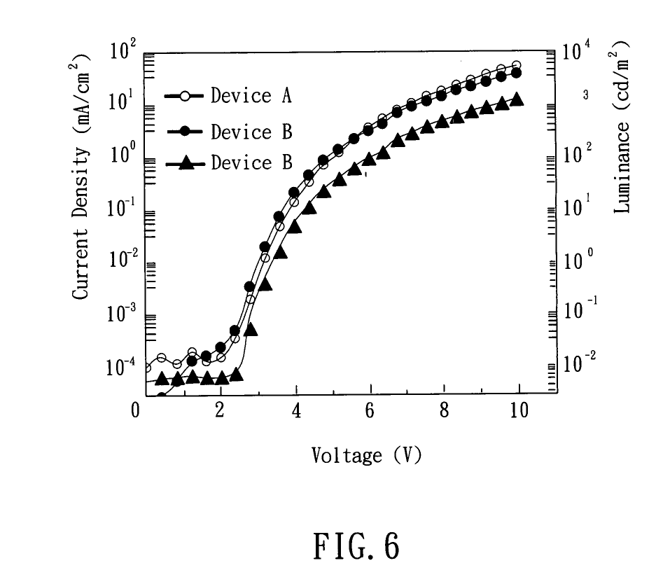

FIG. 6 is the profile of current density and luminance with response to voltage according to the first embodiment of the present invention. As shown in FIG. 6, the top emitting OLED of the present invention also possesses the characteristics of low activating voltage (about 2V) and high luminance. Besides, the character of current density with response to voltage (I-V) shows that the adding of the anti-reflective layer will not influence the device character of the top emitting OLED of the present invention.

### EXAMPLE 2

This example illustrates the raising of contrast character basing on the aforesaid first status of the present invention. Device C is the top emitting OLED disclosed by M. -H. Lu,M. S. Weaver,T. X. Zhou, M. Rothman, R. C. Kwong, M. Hacj, and J. J. Brown in the technical literature published by Appl. Phys. Lett. 81, 3921(2002), of which the structure is similar to that shown in FIG. 2. Wherein, the substrate 91 is a glass substrate, the anode layer 92 is consisted of a layer of of Ag with 100 nm in thickness and a layer of ITO with 16 nm in thickness, the organic material layer 93 is consisted of a layer of CuPc with 20 nm in thickness, a layer of α-NPD with 30 nm in thickness, a layer of CBP:Ir(ppy)₃ with 30 nm in thickness, a layer of BAlq with 10 nm in thickness, and a layer of Alq₃ with 40 nm in thickness, and the transparent cathode layer 94 is consisted of a layer of Ca with 20 nm in thickness and a layer of ITO with 30 nm in thickness.

Device D is the top emitting OLED according to the present invention, of which the structure is similar to that shown in FIG. 4A. Wherein, the substrate 21 is a glass substrate, the first electrode layer 22 is consisted of a layer of Ag with 100 nm in thickness and a layer of ITO with 16 nm in thickness, the organic material layer 23 is consisted of a layer of CuPc with 20 nm in thickness, a layer of α-NPD with 30 nm in thickness, a layer of CBP:Ir(ppy)₃ with 30 nm in thickness, a layer of BAlq with 10 nm in thickness, and a layer of Alq₃ with 40 nm in thickness, the second electrode 24 is consisted of a layer of Ca with 20 nm in thickness and a layer of ITO with 30 nm in thickness, the first dielectric layer 25a is a layer of TeO₂ with refractive index 2.2 and 20 nm in thickness, and the second dielectric layer 25b is a layer of LiF with refractive index 1.36 and 10 nm in thickness.

In Device C and D, Ag/ITO is used as the first electrode layer, of which the layer of ITO is used as an electron injection electrode and the layer of Ag is used as a conductive layer for reducing sheet resistance. In addition, the layer of CuPc is used as the electron hole injection layer, the layer of α-NPD is used as the electron hole transmitting layer, the layer of CBP:Ir(ppy)3 is used as the light-emitting layer, th elayer of Balq is used as the electron hole impediment layer, and the layer of Alq3 is used as the electron transmitting layer, and Ca/ITO is used as the second electrode layer, of which the layer of Ca is acted as an electron injection electrode and the layer of ITO is used as the conductive electrode for reducing sheet resistance. Moreover, in Device D, TeO₂ is used as the high refractive index material (n_{TeO2}=2.2) and LiF is used as the low refractive index material (n_{LiF}=1.36), such that the anti-reflective layer 25 is formed by successively stacking the two materials of high and low refractive indexes.

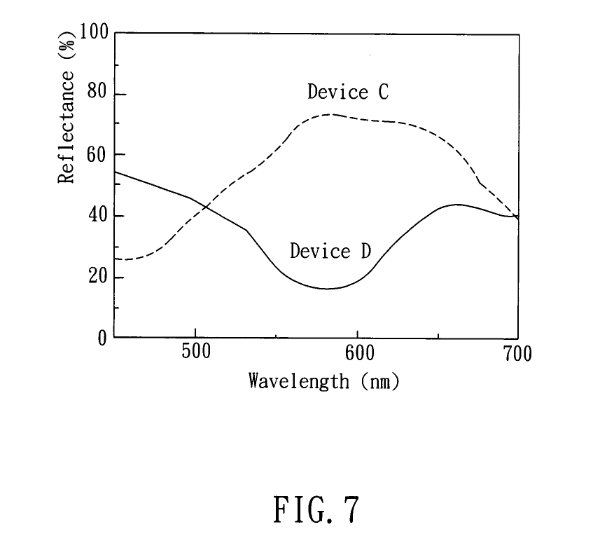

After calculated, the reflectance of Device C in the visible light region is plotted as the dotted line in FIG. 7 showing high reflectance, and that of Device D is plotted as the real line in FIG. 7. The average reflectance of Device C is 50%, and that of improved Device D is reduced to 38%. So the present invention can reduce the reflectance in the visible light region efficaciously. In particular, at the proximity of wavelength 550 nm, the most sensitive wavelength of human being, Device D even can reduce the reflectance to less than 20%, which is very remarkable.

### EXAMPLE 3

This example illustrates the raising of contrast character basing on the aforesaid second status of the present invention. Wherein, the second electrodes of Device E and Device F are cathodes made of nonmetal materials.

Device E is a top emitting OLED, of which the structure is similar to that shown in FIG. 2. Wherein, the substrate 91 is a glass substrate, the anode layer 92 is made of Cr with 100 nm in thickness, the organic layer 93 is consisted of a layer of m-MTDATA with 30 nm in thickness, a layer of α-NPD with 20 nm in thickness, a layer of Alq₃ with 60 nm in thickness and a layer of BCP with 7 nm in thickness, and the transparent cathode layer 94 is made of ITO with 80 nm in thickness.

Device F is a top emitting OLED according to the present invention, of which the structure is similar to that shown in FIG. 4B. Wherein, the substrate 31 is a glass substrate, the first electrode layer 32 is made of Cr with 100 nm in thickness, the organic layer 23 is consisted of a layer of m-MTDATA with 30 nm in thickness, a layer of α-NPD with 20 nm in thickness, a layer of Alq₃ with 60 nm in thickness, and a layer of BCP with 7 nm in thickness, the second electrode 34 is made of ITO with 80 nm in thickness, the anti-reflective layer 35 is made of TeO₂ with refractive index 2.2 and 20 nm in thickness.

In Device E and F, Cr is used as the first electrode layer, the layer of m-MTDATA is used as the electron hole injection layer, the layer of α-NPD is used as the electron transporting layer, the layer Alq₃ is used as the electron transporting/light-emitting layer, and the layer of ITO is used as the second (transparent) electrode layer. Moreover, in Device F, the layer of TeO₂ is used as the anti-reflective layer.

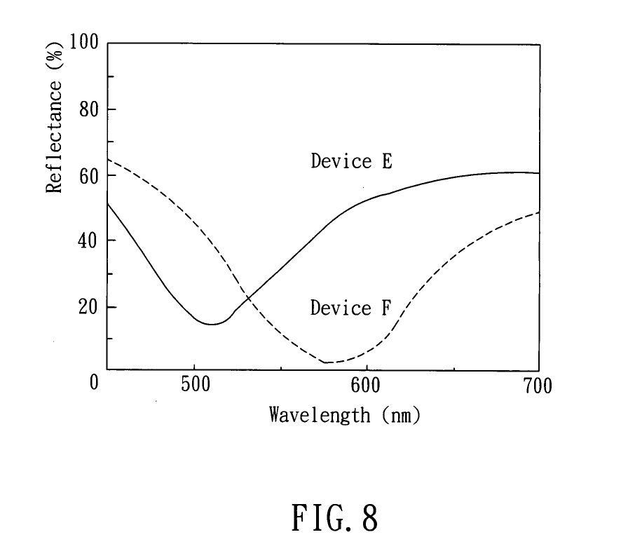

Please refer to FIG. 8, the real line shows the reflectance of Device E and the dotted line shows that of Device F. The average reflectance of Device E is 48% and that of Device F is improved to 37%. Obviously, the additional anti-reflective layer can efficiently reduce the reflectance of Device F in the visible light region. In particular, at the proximity of wavelength 550 nm, the most sensitive wavelength of human being, Device F even can reduce the reflectance to less than 10%, which is remarkable.

### EXAMPLE 4

This example illustrates the raising of contrast character basing on the aforesaid second status of the present invention.

Device G is a top emitting OLED, of which the structure is similar to that shown in FIG. 2. Wherein, the substrate 91 is a glass substrate, the anode layer 92 is made of Cr with 100 nm in thickness, the organic layer 93 is consisted of a layer of m-MTDATA with 30 nm in thickness, a layer of α-NPD with 20 nm in thickness, and a layer of Alq₃ with 60 nm in thickness, and the transparent cathode layer 94 is consisted of a layer of Mg:Ag with 5 nm in thickness and a layer of ITO with 80 nm in thickness.

Device H is a top emitting OLED according to the present invention, of which the structure is similar to that shown in FIG. 4B. Wherein, the substrate 31 is a glass substrate, the first electrode layer 32 is made of Cr with 100 nm in thickness, the organic layer 23 is consisted of a layer of m-MTDATA with 30 nm in thickness, a layer of α-NPD with 20 nm in thickness, a layer of Alq₃ with 60 nm in thickness, the second electrode 34 is consisted of a layer of Mg:Ag with 5 nm in thickness and a layer of ITO with 80 nm in thickness, the anti-reflective layer 35 is a layer of LiF with refractive index 1.36 and 80 nm in thickness.

In Device G and H, Cr is used as the first electrode layer, the layer of m-MTDATA is used as the electron hole injection layer, the layer of α-NPD is used as the electron transmitting layer, the layer of Alq₃ is used as the electron transporting/light-emitting layer, and the multi-layer of Mg:Ag/ITO is used as the second electrode layer, of which the layer of Mg:Ag is used as the electron injection electrode and the layer of ITO is used for the conductive electrode for reducing sheet resistance. Moreover, in Device H, the layer of LiF is used as the anti-reflective layer. In the present example, the layer of ITO can be referred as a layer made of high refractive material, and the layer of LiF can be referred as a layer made of low refractive material, such that the multi-layer structure consisting of the ITO layer and the LiF layer is a combined structure of high refractive material and low refractive material, which is able to function as the first status of the present invention and can achieve the same effect as the aforesaid first statust.

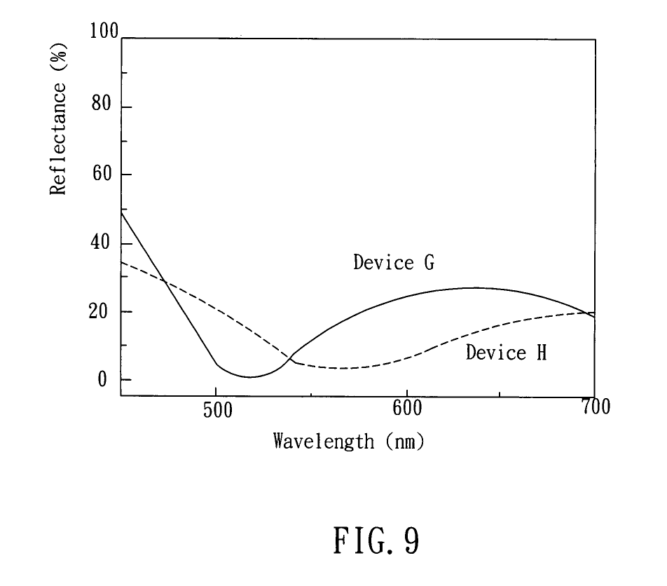

As shown in FIG. 9, the real line shows the reflectance of Device G in the visible light region. The dotted line shows the reflectance of Device H, of which a low refractive index material is stacked onto the second transparent electrode thus efficiently reducing the reflectance in the visible light region. The average reflectance of Device G is 26% and that of Device H is improved to 18%. Obviously, the electrode structure of the present invention can reduce the reflectance in the visible light region and improve the display contrast simultaneously.

### EXAMPLE 5

This example illustrates the raising of contrast character basing on the aforesaid second status of the present invention. The characteristic of this example is that two layers of dielectric acting as an anti-reflective structure is stacked on the transparent second electrode, of which the thickness can be adjust to reduce the reflectance of the device.

The structure of Device G of the present example is the same as that of Example 4 and thus will be not described herein. Device I is the top emitting OLED according to the present invention, of which the structure is similar to that shown in FIG. 4A. Wherein, the substrate 21 is a glass substrate, the first electrode layer 22 is made of Cr with 100 nm in thickness, the organic layer 23 is consisted of a layer of m-MTDATA with 30 nm in thickness, a layer of α-NPD with 20 nm in thickness, a layer of Alq₃ with 60 nm in thickness, the second electrode 24 is consisted of a layer of Mg:Ag with 5 nm in thickness and a layer of ITO with 80 nm in thickness, the first dielectric layer 25a is made of TeO₂ with refractive index 2.2 and 120 nm in thickness, and the second dielectric layer 25b is made of LiF with refractive index 1.36 and 90 nm in thickness.

In Device G and I, Cr is used as the first electrode layer, the layer of m-MTDATA is used as the electron hole injection layer, the layer of α-NPD is used as the electron transporting layer, the layer of Alq₃ is used as the electron transporting/light-emitting layer, and the layer of Mg:Ag/ITO is used as the second electrode layer, of which the layer of Mg:Ag is used as the electron injection electrode and the layer of ITO is used as the conductive electrode for reducing sheet resistance. Moreover, in Device I, the layer of ITO can be referred as a layer made of high refractive material, and the layer of LiF can be referred as a layer made of low refractive material, such that the multi-layer structure consisting of the ITO layer and the LiF layer forms a high/low refractive index layer acted as the anti-reflective layer 25.

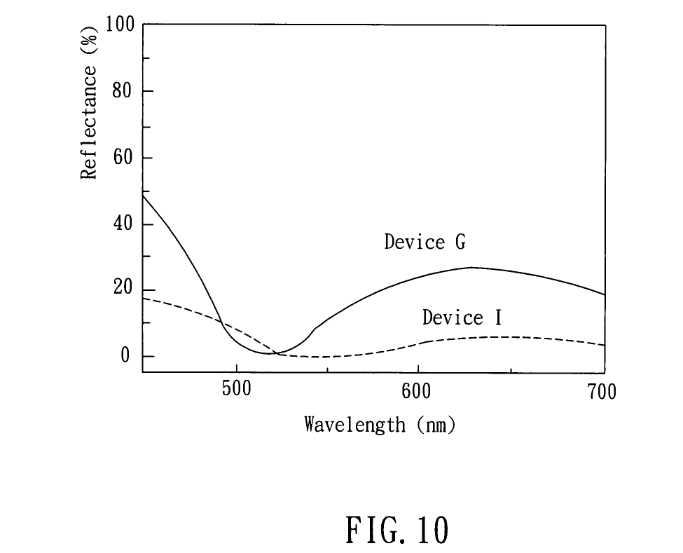

In this example, Device I uses the multi-layer structure made of dielectric materials as the anti-reflective layer. Compared with Device H described in the aforesaid example, Device I in the present example can further improve the reflectance of the electrode structure. As shown in FIG. 10, the average reflectance of Device G is 26% and that of Device I can improve to 6%.

While the preferred embodiments of the present invention have been set forth for the purpose of disclosure, modifications of the disclosed embodiments of the present invention as well as other embodiments thereof may occur to those skilled in the art. Accordingly, the appended claims are intended to cover all embodiments which do not depart from the spirit and scope of the present invention.

What is claimed is:

1. A top emitting organic light emitting device (OLED), comprising:
a substrate;
a first electrode layer, formed on said substrate;
an organic layer, formed on said first electrode layer;
a second electrode layer with a first refractive index, formed on said organic layer; and
an anti-reflective layer with a second refractive index, formed on said second electrode layer; wherein said first refractive index is different from the second refractive index.

2. The top emitting OLED as recited in claim 1, wherein said second electrode has a first thickness and said anti-reflective layer has a second thickness, and said first thickness is matched and cooperated with said second thickness for reducing the reflectance of said OLED on visible light region.

3. The top emitting OLED as recited in claim 1, wherein said first electrode layer is an opaque reflective electrode.

4. The top emitting OLED recited in claim 3, wherein said reflective electrode is made of a metal.

5. The top emitting OLED recited in claim 4, wherein said metal is at least one selected from the group consisting of Au, Ag, Cu, Al, Cr, Mo, Ti, Ni, Pt, Ir, Pd, and the alloy thereof.

6. The top emitting OLED as recited in claim 3, wherein one material selected from the group consisting of metal oxide metal nitride is further formed on said reflective electrode.

7. The top emitting OLED as recited in claim 3, wherein a transparent conductive layer is further formed on said reflective electrode.

8. The top emitting OLED as recited in claim 7, wherein said conductive layer is at least one selected from the group consisting of Indium Tin Oxide (ITO), Indium Zinc Oxide (IZO), and Aluminum Zinc Oxide (AZO).

9. The top emitting OLED as recited in claim 1, wherein said first electrode layer is made of silicon.

10. The top emitting OLED as recited in claim 1, wherein said second electrode is made of a transparent material.

11. The top emitting OLED as recited in claim 10, wherein said transparent material is a metal.

12. The top emitting OLED as recited in claim 11, wherein said metal is at least one selected from the group consisting of Mg, Ca, Al, Ba, Li, Be, Sr, Ag, and Au.

13. The top emitting OLED as recited in claim 10, wherein said transparent material is an organic material selected from the group consisting of organic conductor, organic semiconductor, organic conductor doped with inorganic conductor, and organic semiconductor doped with inorganic conductor.

14. The top emitting OLED as recited in claim 13, wherein said transparent material further includes an electron injection layer stacked and mixed with said organic material.

15. The top emitting OLED as recited in claim 14, wherein said electron injection layer is formed by mixing at least one material selected from the group consisting of LiF, LiO₂, SiO₂, and a metal material.

16. The top emitting OLED as recited in claim 14, wherein said electron injection layer is formed by stacking at least one material selected from the group consisting of LiF, LiO₂, SiO₂, and a metal material.

17. The top emitting OLED as recited in claim 16, wherein the thickness of said metal material is not thicker than 5 nm.

18. The top emitting OLED as recited in claim 10, wherein an inorganic transparent conductor is stacked on said transparent material.

19. The top emitting OLED as recited in claim 10, wherein said inorganic transparent conductor is selected from the group consisting of Indium Tin Oxide (ITO), Indium Zinc Oxide (IZO), and Aluminum Zinc Oxide (AZO), In2O3, SnO2, and ZnO.

20. The top emitting OLED as recited in claim 1, wherein said second electrode layer is made of a transparent material and an electron injection layer by a method selected from the group consisting stacking and mixing.

21. The top emitting OLED as recited in claim 20, wherein said transparent material is a metal.

22. The top emitting OLED as recited in claim 21, wherein said metal is at least one selected from the group consisting of Mg, Ca, Al, Ba, Li, Be, Sr, Ag, and Au.

23. The top emitting OLED as recited in claim 20, wherein said electron injection layer is made of one selected from the group consisting of Al/LiF, Al/LiO₂, and Al/NaCl.

24. The top emitting OLED as recited in claim 1, wherein a transparent conductor is further stacked on said second electrode layer.

25. The top emitting OLED as recited in claim 24, wherein said transparent conductor is selected from the group consisting of Indium Tin Oxide (ITO), Indium Zinc Oxide (IZO), and Aluminum Zinc Oxide (AZO), In2O3, SnO2, and ZnO.

26. The top emitting OLED as recited in claim 10, wherein said transparent material is an inorganic transparent conductor selected from the group consisting of Indium Tin Oxide (ITO), Indium Zinc Oxide (IZO), and Aluminum Zinc Oxide (AZO), In2O3, SnO2, and ZnO.

27. The top emitting OLED as recited in claim 26, wherein said transparent material further includes an electron injection layer stacked and mixed with said inorganic transparent material.

28. The top emitting OLED as recited in claim 27, wherein said electron injection layer is formed by mixingat least one selected from the group consisting of LiF, LiO₂, SiO₂, and a metal material.

29. The top emitting OLED as recited in claim 27, wherein said electron injection layer is formed by stacking at least one selected from the group consisting of LiF, LiO₂, SiO₂, and a metal material.

30. The top emitting OLED as recited in claim 29, wherein the thickness of said metal material is not thicker than 5 nm.

31. The top emitting OLED as recited in claim 1, wherein said anti-reflective layer is formed by stacking at least a first dielectric material and a second dielectric material.

32. The top emitting OLED as recited in claim 31, wherein said first dielectric material and second dielectric material are respectively a material selected from the group consisting of TiO₂, TeO₂, ITO, ZrO, ZnO, Al:ZnO, ZnSe, ZnS, MgO, Si₃N₄, SiO₂, LiF, MgF₂, NaF, and CaF₂.

33. The top emitting OLED as recited in claim 31, wherein the thickness of said first dielectric material is ranged between 5 nm and 120 nm.

34. The top emitting OLED as recited in claim 31, wherein the thickness of said second dielectric material is ranged between 5 nm and 120 nm.
